(19) United States
(12) Patent Application Publication
(10) Pub. No.: US 2024/0371992 A1
(43) Pub. Date: Nov. 7, 2024

(54) FIELD EFFECT TRANSISTOR WITH ENHANCED BUFFER AND BACKBARRIER REGIONS

(71) Applicant: Qorvo US, Inc., Greensboro, NC (US)

(72) Inventors: Jinqiao Xie, Allen, TX (US); Jose Jimenez, Dallas, TX (US); Vipan Kumar, Plano, TX (US)

(21) Appl. No.: 18/626,053

(22) Filed: Apr. 3, 2024

Related U.S. Application Data
(60) Provisional application No. 63/500,106, filed on May 4, 2023.
(60) Provisional application No. 63/500,712, filed on May 8, 2023.

(51) Int. Cl. H01L 29/778; H01L 29/20; H01L 29/207; H01L 29/267

(52) U.S. Cl. CPC H01L 29/7786; H01L 29/2003; H01L 29/207; H01L 29/267

(57) ABSTRACT

A field effect transistor, such as a high electron mobility transistor, comprises a substrate, a buffer region, a backbarrier region, a channel region, a source region, a drain region, and a gate contact. The buffer region is over the substrate and doped with a deep acceptor at a concentration in a range of 2×10¹⁶ cm⁻³ to 1×10¹⁸ cm⁻³. The backbarrier region is over the buffer region and has a thickness in a range of 50 to 5000 Angstroms. The channel region is over the backbarrier region. The source region and the drain region are arranged such that at least a portion of the channel region resides between the source region and the drain region. The gate contact is over the channel region and between the source region and the drain region.

This application claims the benefit of U.S. provisional patent application Ser. No. 63/500,106 filed May 4, 2023 and U.S. provisional patent application Ser. No. 63/500,712 filed May 8, 2023, the disclosures of which are incorporated herein by reference in their entireties.

### FIELD OF THE DISCLOSURE

The present disclosure relates to Field Effect Transistors, such as High Electron Mobility Transistors.

### BACKGROUND

High Electron Mobility Transistors (HEMTs) are a type of field-effect transistor (FET) that have gained significant attention in recent years due to their superior electrical performance in high frequency applications. HEMTs are used in various applications such as amplifiers, oscillators, mixers, and switches. In comparison to traditional metal-oxide-semiconductor field-effect transistors (MOSFETs), HEMTs have a higher electron mobility and lower resistivity, resulting in improved frequency response and output power.

In HEMTs, a two-dimensional electron gas (2 DEG) is formed at the interface between the semiconductors with different bandgap. The 2 DEG is formed at the interface between the semiconductor material (typically GaAs or GaN) and the insulating material (typically AlGaAs or AlGaN). This 2 DEG acts as a conductive channel for the flow of electrons in the HEMT device. This results in a high electron mobility and low resistance channel, allowing the device to operate at high frequencies. HEMTs also have a low noise figure and a high power-added efficiency, making them ideal for radio frequency (RF) applications.

Several materials have been used to fabricate HEMTs, including gallium arsenide (GaAs), indium nitride (InN), gallium nitride (GaN) and aluminum gallium nitride (AlGaN). The material choice affects the device performance, including the maximum operating frequency and the power handling capability. GaAs HEMTs have been widely used in low-to-medium power applications, while GaN and AlGaN HEMTs are generally used for high power applications.

### SUMMARY

One embodiment of the disclosure relates to a field effect transistor, such as a high electron mobility transistor. The field effect transistor comprises a substrate, a buffer region, a backbarrier region, a channel region, a source region, a drain region, and a gate contact. The buffer region is over the substrate and doped with deep levels (deep acceptors or donors) at a concentration in a range of 1×10¹⁶ cm⁻³ to 1×10¹⁹ cm⁻³. The backbarrier region is over the buffer region and has a thickness in a range of 50 to 5000 Angstroms. The channel region is over the backbarrier region. The source region and the drain region are arranged laterally such that at least a portion of the channel region resides between the source region and the drain region. The gate contact is over the channel region and between the source region and the drain region.

In one embodiment, the buffer region is formed from gallium nitride (GaN), and the backbarrier region is formed from aluminum gallium nitride (AlGaN).

In one embodiment, the buffer region is doped with the deep acceptor at a concentration in a range of 2×10¹⁷ cm⁻³ to 5×10¹⁷ cm⁻³.

In one embodiment, the thickness of the backbarrier region is in a range of 200 to 2000 Angstroms.

In one embodiment, the thickness of the backbarrier region is in a range of 500 to 1500 Angstroms.

In one embodiment, the deep acceptor is carbon.

In one embodiment, the substrate is formed from silicon carbide (SiC).

In one embodiment, the substrate is formed from SiC; the buffer region is formed from GaN; the backbarrier region is formed from AlGaN; and the buffer region is doped with the deep acceptor at a concentration in a range of 2×10¹⁷ cm⁻³ to 5×10¹⁷ cm⁻³.

In one embodiment, the backbarrier region is formed from AlₓGa₁₋ₓN, wherein x=0.01-0.15.

In one embodiment, wherein the thickness of the backbarrier region is in a range of 100 to 4000 Angstroms.

In one embodiment, the thickness of the backbarrier region is in a range of 500 to 1500 Angstroms.

In one embodiment, the field effect transistor further comprises:
a spacer region over the channel region;
a top barrier region over the spacer region; and
a cap region over the top barrier region, wherein:
the gate contact is over the cap region;
the spacer region is formed from aluminum nitride (AlN);
the barrier region comprises AlGaN, and
the cap region comprises GaN.

In one embodiment, the channel region has a thickness in a range of 30 to 500 Angstroms.

In one embodiment, the field effect transistor further comprises:
a spacer region over the channel region;
a top barrier region over the spacer region; and
a cap region over the top barrier region, wherein the gate contact is over the cap region.
In one embodiment, the substrate is formed from SiC; the spacer region is formed from AlN; the barrier region comprises AlGaN;
and the cap region comprises GaN.

In one embodiment, a method of fabricating a field effect transistor comprises:
providing a substrate;
providing a buffer region over the substrate and doped with a deep acceptor dopant at a concentration in a range of 1×10¹⁶ cm⁻³ to 1×10¹⁹ cm⁻³;
providing a backbarrier region over the buffer region having a thickness in a range of 50-5000 Angstroms;
providing a channel region over the backbarrier region;
providing a source region and a drain region arranged such that at least a portion of the channel region resides between the source region and the drain region; and
providing a gate contact over the channel region and between the source region and the drain region.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a HEMT configured according to one embodiment of the disclosure.

FIG. 2 is a band diagram for the HEMT of FIG. 1.

FIG. 3 is a thermal conductivity diagram of SiC, GaN, and several AlGaN ternaries versus temperature.

FIG. 4 is a band diagram for four different exemplary HEMTs.

FIG. 5 is a block diagram of a communication device, such as a mobile terminal.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The concepts described herein provide a buffer structure for a field-effect transmitter (FET), such as a high electron mobility transmitter (HEMT). The buffer structure has at least two distinct regions. The first region is a thin ternary layer that is close to the channel region and referred to as a backbarrier region. The backbarrier region is thin enough not to degrade the overall thermal properties of the overall buffer structure, but possesses spontaneous, piezoelectric polarization properties, and band discontinuity that create confinement for free electron in conducting channel. The second region is a thicker layer, which is below the backbarrier region and referred to as a buffer region. The buffer region has good thermal properties to allow for heat spreading with reduced temperature penalty. The buffer region is doped with deep level traps to avoid the formation of a secondary channel that could negatively impact the RF performance of the structure. Prior to delving into the details of these two regions, an overview of an exemplary device structure is provided.

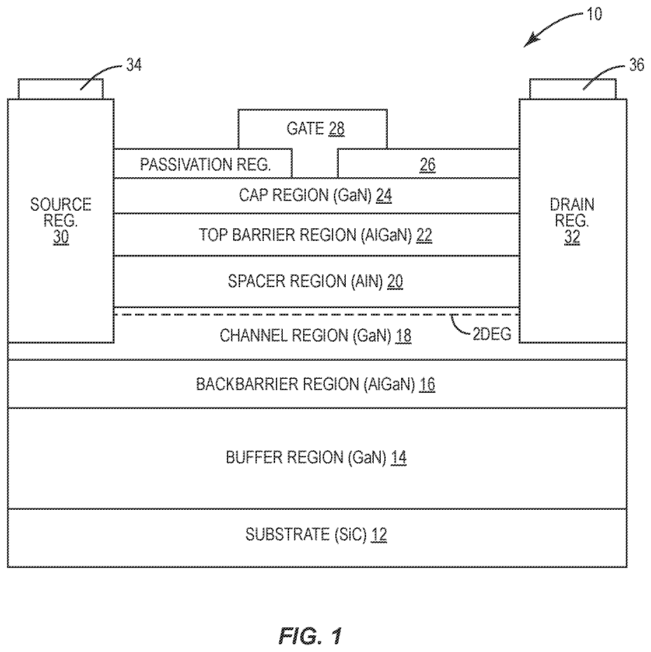

With reference to FIG. 1, a HEMT 10 is illustrated with the dual-region buffer structure according to the present disclosure. The HEMT 10 includes an epitaxial structure formed over a substrate 12. Within the epitaxial region, a buffer region 14 is provided over the substrate 12. A backbarrier region 16 is provided over the buffer region 14. A channel region 18 is provided over the backbarrier region 16. A spacer region 20 is provided over the channel region 18. A top barrier region 22 is provided over the spacer region 20. A cap region 24 is provided over the barrier region 22, and a passivation region 26 is provided over the cap region 24.

A gate 28 is formed over the passivation region 26 and may extend through an opening in the passivation region 26 to the cap region 24. In the illustration embodiment, the gate 28 has a T-shaped cross-section wherein the bottom, vertical portion of the “T” extends through the passivation region 26 and the top, horizontal portions of the “T” resides over portions of the passivation region 26. Those skilled in the art will recognize alternative gate structures.

Source and drain regions 30, 32 extend into the epitaxial structure of the HEMT 10 on opposing sides of the gate 28. As illustrated, the source and drain regions 30, 32 extend past the passivation region 26, the cap region 24, the top barrier region 22, and the spacer region 20, and into the channel region 18. The size, location, and relative placement of the source and drain regions 30, 32 may vary from one application to another. A source contact 34 is provided over the source region 20, and a drain contact 36 is provided over the drain region 32. The dashed line in the channel region 18 represents the 2 DEG (two-dimensional electron gas), which corresponds to the conducting channel when the HEMT 10 is on and electrons are flowing in the channel region 18 between the source and drain regions 30, 32.

In the illustrated embodiment, the substrate 12 is formed from silicon carbide (SiC), but other non-limiting materials include gallium nitride (GaN), gallium arsenide (GaAs), sapphire, Silicon, and the like. Exemplary, non-limiting, thickness ranges for the substrate 12 include 50 um to 1 mm and the like. The substrate 12 may be doped with a p-type material at concentrations ranging from 1×10¹⁵ cm⁻³ to 1×10¹⁹ cm⁻³.

The buffer region 14 is formed from GaN,. Exemplary, non-limiting, thickness ranges for the buffer region 14 may be 100 nm to 2000 nm and the like. The buffer region 14 may be doped with a acceptors, such as carbon (C), Zinc (Zn), magnesium (Mg), and beryllium (Be) at concentrations ranging from 2×10¹⁷ cm⁻³ to 5×10¹⁷ cm⁻³, 5×10¹⁶ cm⁻³ to 1×10¹⁸ cm⁻³, and 1×10¹⁵ cm⁻³ to 5×10¹⁷ cm⁻³. The doping concentrations may be uniform or may be graded in either direction.

The backbarrier region 16 is formed from aluminum gallium nitride (AlGaN), but other non-limiting materials include InAlGaN, InAlN, and the like. Exemplary non-limiting thickness ranges for the backbarrier region 16 include 200-2000 Å, 500-1500 Å, 50-5000 Å, and the like. The backbarrier region 16 may be doped with deep levels at concentrations ranging from 1×10¹⁵ cm⁻³ to 5×10¹⁷. The doping concentrations may be uniform or may be graded in either direction. If AlGaN is used for the backbarrier, the range of aluminum for the AlGaN is between 0.5% to 15%, 2% to 12%, 5% to 10%, and the like (i.e. AlₓGa₁₋ₓN, wherein x=0.5-15, 2-12, 5-10).

The channel region 18 is formed from GaN, but other non-limiting materials include InGaN, AlGaN, and the like. Exemplary non-limiting thickness ranges for the channel region 18 include 30 Å to 500 Å, and the like. The spacer region 20 is formed from AlN.

The top barrier region 22 may take on various configurations. Three exemplary, yet non-limiting, configurations are illustrated. In a first configuration, the top barrier region 22 comprises AlₓGa₁₋ₓN, wherein x=15-60%. In other scenarios, x=20-50%, or x=30-45%. The thickness of the barrier layer 22 may range from 50-300 Angstroms (Å) in certain embodiments, but other ranges are envisioned.

In a second configuration, the top barrier region 22 comprises AlₓIn_{y}Ga_{1-x-y}N, wherein x=90-70% and y=10-30%. Again, the thickness of the top barrier region 22 may range from 30-300 Angstroms (Å) in certain embodiments, other ranges are envisioned.

In a third configuration, the top barrier region 22 comprises AlₓSc_{y}Ga_{1-x-y}N, wherein x=95-70% and y=5-30%. Again, the thickness of the barrier layer 22 may range from 30-300 Å in certain embodiments, other ranges are envisioned.

The cap region 24 is formed from GaN, but other non-limiting materials include SiNx, AlN, and the like. Exemplary, non-limiting, thickness ranges for the cap region 24 include 5 A to 50 A, and the like.

The passivation region 26 is formed from SiNx, but other non-limiting materials include AIOx, SiNxOy, and the like. Exemplary, non-limiting, thickness ranges for the passivation layer 26 include 50 A to 1500 A, 400 A to 2000a and the like.

The source and drain regions 30, 32 may be doped with an n-type material at concentrations ranging from 1×10¹⁹ cm⁻³ to 5×10²⁰ cm⁻³.

The gate contact 28 is formed from Ni/Au, but other non-limiting materials include TiW, TiN, and the like. The source and drain contacts 34, 36 are formed from GaN, but other non-limiting materials including Pt and the like may be used.

In typical FETs, the primary role of a buffer region is that of isolating the highly defective substrate-epitaxial interface from the electron channel to assure good electron mobility and transport performance. In GaN-based FETs, a GaN buffer region is typically as thick as 1.8 um, but may often range from 100 nm to 4 um depending on the application.

In GaN FETs, the GaN buffer is typically doped with deep level traps such as Iron (Fe), Carbon (C) or Zinc (Zn) to compensate for the shallow donors produced by the incorporation of Oxygen (O) or Silicon (Si) that is generally present during GaN growth. Those types of buffers are highly effective on large gate FET structures as they are able to sustain the large fields present in GaN FET transistors without degrading the transconductance or breakdown voltage scaling capabilities (i.e. typical 40V per um of gate-drain spacing). These buffer regions are also good thermally due to the excellent thermal properties of GaN, thus allowing for an efficient initial critical heat spreading around the heat generating region of the device. These heat generating regions are associated with the depletion region, or channel region, around the gate-drain edge of the transistor channel, where most of the voltage drops.

In ultra-high frequency GaN FETs, the length of the gate 28 is reduced to minimize the intrinsic transistor charging capacitance, and thus improve its RF performance. Under these conditions, a typical GaN buffer region becomes inadequate. For ultra-scaled GaN FETs, a more sophisticated buffer structure is needed and described herein. This new buffer structure, which includes the buffer region 14 and backbarrier region 16, should allow for isolation between the channel region 18 and buffer region-substrate interface (14/12) and prevent the spilling of electrons from the channel region 18 into the buffer region 14, which limits the switching properties of the gate 28. In an effort to improve the typical buffer region, others have introduced ternary backbarriers (typical with 4% content but ranging from as low as 1% and as high as 10%). In AlGaN backbarriers, the anti-spilling properties are achieved with the barrier created by the spontaneous and piezoelectric polarization fields between the GaN channel region and the AlGaN buffer.

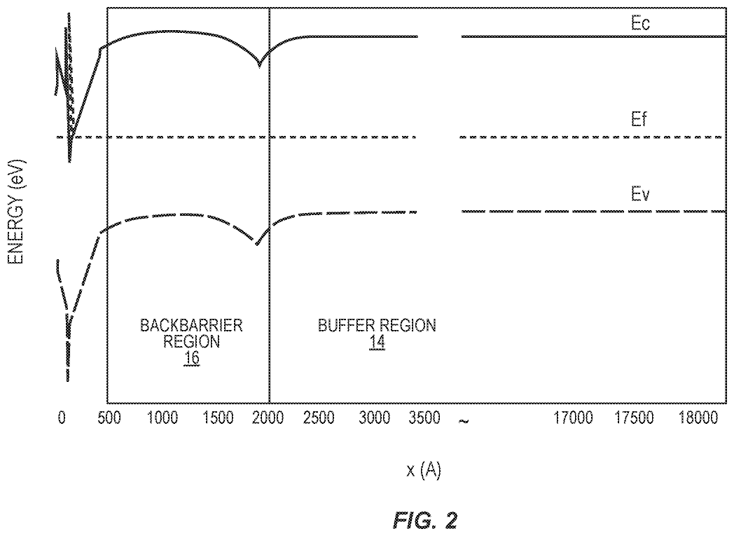

FIG. 2 is a band diagram of the new buffer structure that employs an appropriately configured buffer region 14 and backbarrier region 16. Under such band profiles, the electrons in the channel region 18 are confined to the channel region 18 and any spilling to the buffer region 14 is reduced or eliminated even at high electric fields. This in turn has a positive effect on the transistor RF performance, reducing the short channel effects and thus the transconductance degradation, ultimately achieving high gain transistors even at relative low drain current bias. Notably, high gain at low drain current bias is a highly desirable transistor quality that allows high gain and efficiency simultaneously.

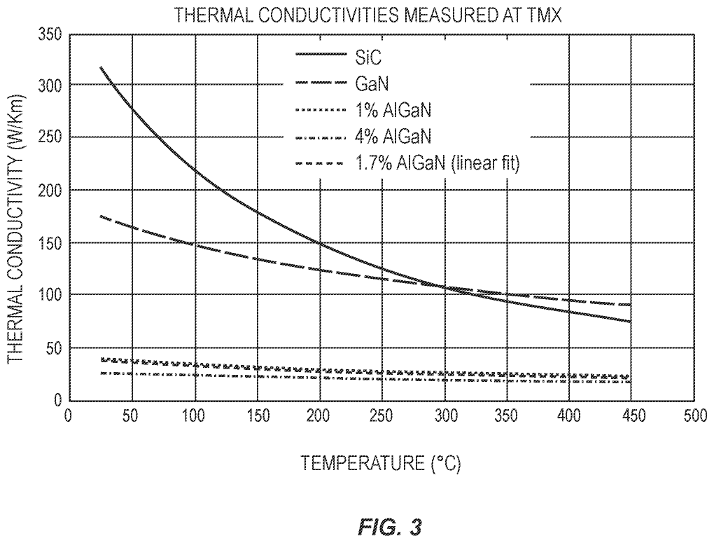

One of the problems of ternary buffers such as the typical ones described above are their poor thermal properties. FIG. 3 provides a comparison of thermal conductivity (W/Km) of SiC, GaN, 1% AlGaN ternary, 4% AlGaN ternary, and 1.7% AlGaN ternary (linear fit). The degradation of thermal properties has important implications in device performance and reliability. As such, there is a need for an improved buffer structure for FETs, including HEMTs.

As mentioned earlier, the new hybrid buffer structure has two different regions: a backbarrier region 16 and buffer region 14. The backbarrier region 16 may be a thin ternary (AlGaN) layer that is close to the channel region 18, is thin enough not to degrade the overall thermal properties of the overall buffer structure (i.e. both the backbarrier region 16 and the buffer region 14), and has spontaneous, piezoelectric polarization properties and band discontinuity that create confinement for electron. The buffer region 14 is a thicker GaN layer that has good thermal properties to allow for heat spreading with reduced temperature penalty, and is doped with deep levels to avoid the formation of a secondary channel that could ruin the RF performance of the structure.

The hybrid buffer is designed so that on one side, the backbarrier region 16 is thin enough to reduce the opportunity of forming a secondary channel that could ruin the RF performance. On the other side, the backbarrier region 16 is designed to be thick enough to separate the channel from the intentionally introduced deep levels whose trapping and de-trapping dynamics could negatively affect the performance of the transistor.

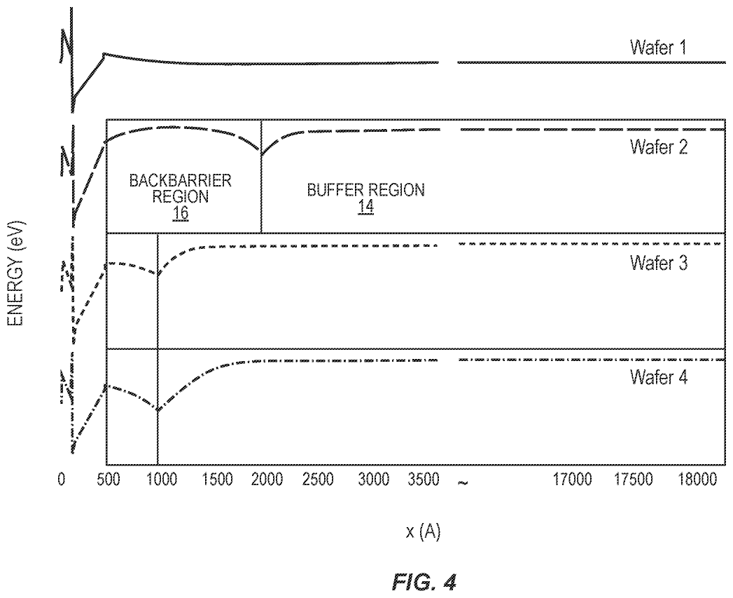

FIG. 4 shows the band diagram for four exemplary structures, which are executed on four different wafers. Wafer 1 employs a traditional buffer structure. Wafers 2, 3, and 4 employ variations of the hybrid buffer structure described herein. Wafer 2 has a relatively large AlGaN backbarrier region 16 to isolate the channel region 18 from the intentionally introduced deep traps on the GaN buffer 14 to prevent formation of a secondary channel formation. Wafer 3 is similar to wafer 2, but with a thinned AlGaN backbarrier region 16. Wafer 4 is similar to wafer 3, but with a lower amount of deep level traps in the GaN buffer region 14. The epitaxial makeup for wafers 1-4 is shown in Table 1.

TABLE 1

| | Cap | Top Barrier | Spacer | Channel | Backbarrier | Buffer |
|---|---|---|---|---|---|---|
| | Region 24 | Region 22 | Region 20 | Region 18 | Region 16 | Region 14 |
| Wafer 1 | 12Å GaN | 90Å 29% | 10Å | 300Å GaN | N/A | 4% AlGaN |
| | | AlGaN | AlN | | | |
| Wafer 2 | 12Å GaN | 90Å 29% | 10Å | 300Å GaN | 1500Å 5% | GaN (doped |
| | | AlGaN | AlN | | AlGaN | w/C 5 × 10¹⁷) |
| Wafer 3 | 12Å GaN | 90Å 29% | 10Å | 300Å GaN | 500Å 5% | GaN (doped |
| | | AlGaN | AlN | | AlGaN | w/C 5 × 10¹⁷) |
| Wafer 4 | 12Å GaN | 90Å 29% | 10Å | 300Å GaN | 500Å 5% | GaN (doped |
| | | AlGaN | AlN | | AlGaN | w/C 2 × 10¹⁷) |

Tables 2 and 3 show selected small signal and large signal RF performance for each of wafers 1-4.

TABLE 2

| | FT (cutoff frequency) | Gain at 40 GHz |
|---|---|---|
| | (GHz) | (dB) |
| Wafer 1 | 10 V, 200 MA/mm: 84.64 | 10 V, 200 MA/mm: 12.40 |
| | 15 V, 100 MA/mm: 72.79 | 15 V, 100 MA/mm: 12.41 |
| | 15 V, 200 MA/mm: 74.72 | 15 V, 200 MA/mm: 12.82 |
| Wafer 2 | 10 V, 200 MA/mm: 84.52 | 10 V, 200 MA/mm: 12.53 |
| | 15 V, 100 MA/mm: 73.82 | 15 V, 100 MA/mm: 12.81 |
| | 15 V, 200 MA/mm: 75.11 | 15 V, 200 MA/mm: 13.18 |
| Wafer 3 | 10 V, 200 MA/mm: 79.27 | 10 V, 200 MA/mm: 13.13 |
| | 15 V, 100 MA/mm: 65.62 | 15 V, 100 MA/mm: 13.64 |
| | 15 V, 200 MA/mm: 63.46 | 15 V, 200 MA/mm: 12.06 |
| Wafer 4 | 10 V, 200 MA/mm: 88.19 | 10 V, 200 MA/mm: 12.76 |
| | 15 V, 100 MA/mm: 72.14 | 15 V, 100 MA/mm: 12.86 |
| | 15 V, 200 MA/mm: 76.00 | 15 V, 200 MA/mm: 13.51 |

TABLE 3

| | Power Added | | | |
|---|---|---|---|---|
| | Efficiency | Power | Associate | Small Signal |
| | (PAE) | Density | Gain | Gain |
| | (%) | (W/mm) | (dB) | (dB) |
| Wafer 1 | 49.13 | 2.20 | 8.72 | 10.72 |
| Wafer 2 | 49.01 | 1.90 | 8.86 | 10.76 |
| Wafer 3 | 43.17 | 1.27 | 9.18 | 10.90 |
| Wafer 4 | 48.99 | 1.79 | 9.07 | 11.22 |

From the data in Tables 2 and 3, the hybrid buffer structures of wafers 2-4 can achieve effectively the same cutoff frequency (FT), small signal gain, and large signal efficiency as that of the traditional, non-hybrid buffer structure of wafer 1 (the standard AlGaN backbarrier). However, the hybrid structures of wafers 2-4 do that at a much lower thermal resistance, and thus, better reliability at the same stress levels.

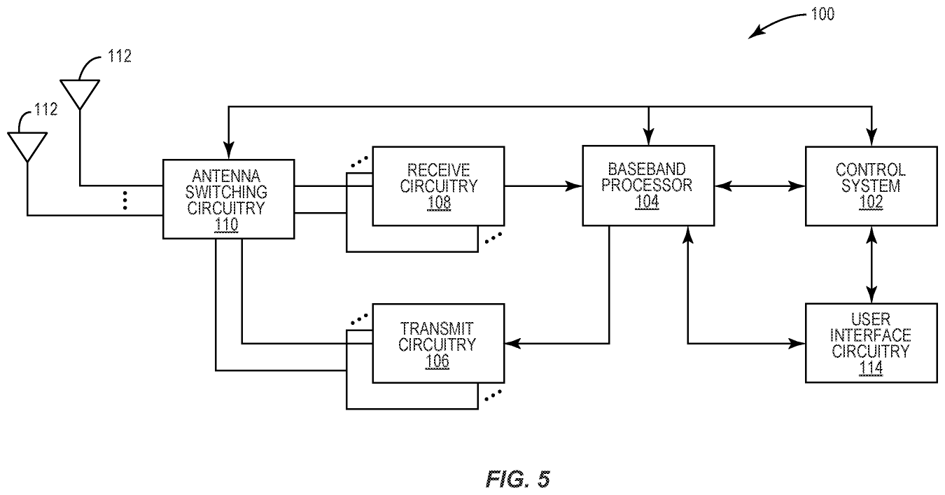

With reference to FIG. 5, the concepts described above may be implemented in various types of user elements 100, such as mobile terminals, smart watches, tablets, computers, navigation devices, access points, and like wireless communication devices that support wireless communications, such as cellular, wireless local area network (WLAN), Bluetooth, and near field communications. The user elements 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA) or an application-specific integrated circuit (ASIC), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter of the receive circuitry 108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed on greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art. HEMTs 10 may be implemented in the power amplifier circuitry of the transmit circuitry 106, the receive circuitry 108, and/or the antenna switching circuitry 110.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A field effect transistor comprising:
a substrate;
a buffer region over the substrate and doped with a deep acceptor at a concentration in a range of 1×10¹⁶ cm⁻³ to 1×10¹⁹ cm⁻³;
a backbarrier region over the buffer region having a thickness in a range of 50 to 5000 Angstroms;
a channel region over the backbarrier region;
a source region and a drain region arranged such that at least a portion of the channel region resides between the source region and the drain region; and
a gate contact over the channel region and between the source region and the drain region.

2. The field effect transistor of claim 1 wherein the buffer region is formed from gallium nitride (GaN), and the backbarrier region is formed from aluminum gallium nitride (AlGaN).

3. The field effect transistor of claim 2 wherein the buffer region is doped with the deep acceptor at a concentration in a range of 2×10¹⁶ cm⁻³ to 5×10¹⁷ cm⁻³.

4. The field effect transistor of claim 2 wherein the thickness of the backbarrier region is in a range of 200 to 2000 Angstroms.

5. The field effect transistor of claim 2 wherein the thickness of the backbarrier region is in a range of 500 to 1500 Angstroms.

6. The field effect transistor of claim 2 wherein the deep acceptor is carbon.

7. The field effect transistor of claim 2 wherein the substrate is formed from silicon carbide (SiC).

8. The field effect transistor of claim 1 wherein:
the substrate is formed from silicon carbide (SiC);
the buffer region is formed from gallium nitride (GaN);
the backbarrier region is formed from aluminum gallium nitride (AlGaN); and
the buffer region is doped with the deep acceptor at a concentration in a range of 2×10¹⁶ cm⁻³ to 5×10¹⁷ cm⁻³.

9. The field effect transistor of claim 8 wherein the thickness of the backbarrier region is in a range of 200 to 2000 Angstroms.

10. The field effect transistor of claim 8 wherein the thickness of the backbarrier region is in a range of 500 to 1500 Angstroms.

11. The field effect transistor of claim 10 wherein the deep acceptor dopant is carbon.

12. The field effect transistor of claim 8 wherein the deep acceptor is carbon.

13. The field effect transistor of claim 12 further comprising:
a spacer region over the channel region;
a top barrier region over the spacer region; and
a cap region over the top barrier region, wherein:
the gate contact is over the cap region;
the spacer region is formed from aluminum nitride (AlN);
the top barrier region comprises aluminum, gallium, and nitride (AlGaN); and
the cap region comprises gallium nitride (GaN).

14. The field effect transistor of claim 8 wherein the backbarrier region is formed from AlₓGa₁₋ₓN, wherein x=0.01-0.15.

15. The field effect transistor of claim 1 wherein the backbarrier region is formed from AlₓGa₁₋ₓN, wherein x=0.01-0.15.

16. The field effect transistor of claim 15 wherein the channel region has a thickness in a range of 30 to 500 Angstroms.

17. The field effect transistor of claim 1 wherein the channel region has a thickness in a range of 30 to 500 Angstroms.

18. The field effect transistor of claim 1 further comprising:
a spacer region over the channel region;
a top barrier region over the spacer region; and
a cap region over the top barrier region, wherein the gate contact is over the cap region.

19. The field effect transistor of claim 18 wherein:
the substrate is formed from silicon carbide (SiC);
the spacer region is formed from aluminum nitride (AlN);
the top barrier region comprises aluminum gallium nitride (AlGaN); and
the cap region comprises gallium nitride (GaN).

20. The field effect transistor of claim 1 wherein the field effect transistor is a high electron mobility transistor.

21. A method of fabricating a field effect transistor comprising:
providing a substrate;
providing a buffer region over the substrate and doped with a deep acceptor at a concentration in a range of 5×10¹⁶ cm⁻³ to 1×10¹⁸ cm⁻³;
providing a backbarrier region over the buffer region having a thickness in a range of 50-5000 Angstroms;
providing a channel region over the backbarrier region;
providing a source region and a drain region arranged such that at least a portion of the channel region resides between the source region and the drain region; and
providing a gate contact over the channel region and between the source region and the drain region.

22. A user element comprising transmit and receive circuitry wherein at least one of the transmit and receive circuitry comprises a field effect transistor comprising:
a substrate;
a buffer region over the substrate and doped with a deep acceptor at a concentration in a range of 1×10¹⁶ cm⁻³ to 1×10¹⁹ cm⁻³;
a backbarrier region over the buffer region having a thickness in a range of 50 to 5000 Angstroms;
a channel region over the backbarrier region;
a source region and a drain region arranged such that at least a portion of the channel region resides between the source region and the drain region; and
a gate contact over the channel region and between the source region and the drain region.
